(19) United States
(12) Patent Application Publication
(10) Pub. No.: US 2012/0268216 A1
(43) Pub. Date: Oct. 25, 2012

(54) Dual-Sensor Temperature Stabilization for Integrated Electrical Component

(75) Inventor: Jonathan Borremans, Lier (BE)

(73) Assignee: IMEC, Leuven (BE)

(21) Appl. No.: 13/512,746

(22) PCT Filed: Nov. 30, 2010
(86) PCT No.: PCT/EP2010/068577

§ 371 Date: Jun. 28, 2012

Related U.S. Application Data
(60) Provisional application No. 61/265,068, filed on Nov. 30, 2009.

(51) Int. Cl. H03L 1/04; H02N 1/00

(52) U.S. Cl. 331/70; 310/300

(57) ABSTRACT

Method and system (1) for stabilizing a temperature (Tcomp) of an integrated electrical component, placed in an oven, at a predefined temperature (Tset). The temperature of the integrated electrical component is sensed by means of temperature sensing means, comprising a first resp. second sensing element (61, 62) located in good thermal contact with the integrated electrical component, the first resp. second sensing elements (61, 62) having a first resp. second temperature dependent characteristic (63, 64), the second temperature dependency being different from the first temperature dependency such that the first and second characteristics (63, 64) intersect at the predefined temperature (Tset), and a sensing circuit (72) adapted for sensing the first and the second sensing elements (61, 62) and for supplying a first resp. second measurement signal (83, 84) indicative of the first resp. second temperature dependent characteristics (63, 64) to a control circuit (71), which determines a control signal for the heating means therefrom.

### TECHNICAL FIELD

The present invention relates generally to a temperature control system, in particular to an ovenized dual-sensor control system and a method for stabilizing the temperature for an integrated electrical component.

### BACKGROUND ART

It is known that Micro-electromechanical systems (MEMS) and in particular MEMS resonators possess a very high quality factor (Q), and can be used to build oscillators, which makes them viable to serve as frequency reference devices, as illustrated in FIG. 1. Traditionally however quartz crystals are often used as a frequency reference because of their better temperature stability. When higher stability is required, such as in broadcast transmitter systems, an oven controlled crystal oscillator is often used. However, such quartz device is large and a system using a quartz reference suffers from a low level of integration. MEMS oscillators on the other hand are small, and can be integrated, thus lowering the cost significantly. However, MEMS resonators without compensation show a high sensitivity of frequency drift over temperature (e.g. +−5000 ppm over a 100° C. ambient temperature range), and thus have a less stable frequency characteristic over temperature than a quartz crystal, as illustrated in FIG. 2.

A MEMS resonator can be stabilized better over a wide ambient temperature range (e.g. a 100° C. ambient temperature range) by sensing the ambient temperature, and by compensating the MEMS resonator e.g. electrically, depending on the measured temperature. FIG. 3 illustrates such a prior art solution. The ambient temperature is sensed by an external temperature sensor in good thermal contact with the MEMS device, and the MEMS oscillator system is compensated electrically by a frequency control means based on the measured temperature. In other words, an ambient temperature sensor drives a frequency compensation knob of the resonator system. In this way the MEMS resonator may typically be controlled up to +−100 ppm accuracy over a 100° C. ambient temperature range (e.g. from −20° C. to +80° C. ambient temperature).

A problem however with these mechanisms is the accuracy and temperature stability of the temperature sensors themselves. Their own drift over temperature limits the achievable temperature stability of the MEMS resonator, which is why a reliable (and expensive) temperature reference is often needed in such systems.

Patent application US 2009/0243747 uses two resonators to generate one stable frequency, as shown in FIG. 4. Temperature stability is achieved by using two resonators having a different temperature coefficient of frequency, TCF=Δf/f.1/ΔT, being the variation of the frequency per temperature variation, and by compensating for the frequency difference between the resonators due to temperature drift. A predetermined temperature Tset exists where both frequencies are identical (if no compensation was applied). The control loop compensates for the temperature variations and ensures the frequencies are maintained identical also for other temperatures. Therefore, stability of the resonator frequency is achieved. This concept however has the disadvantage of requiring two resonators with a different temperature coefficient of frequency (TCF), requiring a lot of chip-area. Also, both resonators should be configured as oscillators, requiring additional circuitry. Also, to achieve the desired frequency, the temperature at both resonator bars should be identical, which may be conceptually easy by matching the designs, but in practice very hard to guarantee.

### DISCLOSURE OF THE INVENTION

It is an aim of the present invention to provide a system and a method for stabilizing a temperature of an integrated electrical component at a predefined temperature (Tset), which are less complex.

This aim is achieved according to the present invention with the system and method of the independent claims.

Thereto the present invention provides an ovenized system for stabilizing a temperature of an integrated electrical component at a predefined temperature, comprising:
a heating means for heating an oven to an oven temperature;
an electrical device placed in the oven, the electrical device comprising the integrated electrical component, the integrated electrical component having a temperature dependent characteristic;
a temperature sensing means for sensing the temperature of the integrated electrical component;
a control circuit connected to the temperature sensing means for receiving measurement signals indicative of the sensed temperature and connected to the heating means for supplying a control signal thereto, to maintain the temperature of the integrated electrical component at the predefined temperature;

wherein the temperature sensing means comprises:
a first resp. second sensing element located in good thermal contact with the integrated electrical component such that the sensing elements have substantially the same temperature as the integrated electrical component, the first resp. second sensing elements having a first resp. second temperature dependent characteristic, the second temperature dependency being different from the first temperature dependency such that the first and second characteristics intersect at the predefined temperature;
a sensing circuit adapted for sensing the first and the second sensing elements and for supplying a first resp. second measurement signal indicative of the first resp. second temperature dependent characteristics to the control circuit.

The integrated electrical component may e.g. be a micro-electro-mechanical system (MEMS) device, e.g. a MEMS resonator or an electrical component such as e.g. a capacitor, a resistor etc. In this application the terms “MEMS structure”, “MEMS component” and “MEMS device” are used as synonyms.

The integrated electrical component can be a capacitor, a resistor, an inductor, a current source, a voltage source, an ADC converter, an amplifier or any other integrated electrical component known to the person skilled in the art.

By using two sensing elements in sufficiently good thermal contact with the integrated electrical component so that they have substantially the same temperature as the integrated electrical component, and both sensing elements having different temperature dependent characteristics such that when measured the measurement curves intersect in a predefined intersection point corresponding to the predefined temperature Tₛₑₜ, it is possible to easily determine if the actual temperature of the integrated electrical component is above or below or equal to predetermined temperature Tₛₑₜ, and controlling the heater correspondingly. By using the measured signals in a control loop, the desired temperature can be accurately maintained.

By adding two sensing elements having different temperature dependencies to sense the actual temperature of the integrated electrical component instead of providing two integrated electrical components having different temperature dependencies (as used in the art), redundant circuitry can be avoided, as a single integrated electrical component can be used and optimized to fulfil the desired function (e.g. accelerometer, resonator, pressure meter, etc) without having to take into account temperature drift, since the sensing means are present to compensate for any temperature drift of the integrated electrical component.

By separating the function of temperature sensing from the desired function of the MEMS structure, trimming (e.g. laser trimming) or calibration of the sensing elements can be implemented to slightly modify their characteristics without affecting the MEMS structure and without introducing unwanted side effects thereto.

Since only the relative temperature error needs to be detected (i.e. detect whether the actual temperature is greater or smaller than the desired temperature), no absolute measure of the amplitude of the error needs to be detected. Therefore, no amplifier nor analog-to-digital converters are needed, which would have needed highly accurate and stable characteristics over temperature. This greatly simplifies the system, rendering it more feasible. Gain errors in detection of the temperature error is irrelevant for achieving the wanted Tset, since the only relevant measure is ‘too high’ or ‘too low’. Not exactly how much too high or too low.

Another advantage is that the technique of the present invention can be used for a wide variety of MEMS structures and other integrated electrical components, not only for MEMS resonators.

Preferably, but not necessarily, the first resp. the second sensing elements are sensed with a first resp. second sensing signal, which are preferably identical, meaning e.g. that the sensing signals have substantially the same amplitude, but not necessarily the same sign or phase or duration.

In an embodiment the control circuit is adapted for subtracting the first and the second measurement signals, resulting in a difference signal, and for amplifying the difference signal, and for providing the amplified difference signal as the control signal.

Such control circuit can be easily implemented requiring a minimal of hardware resources (i.e. chip area and power consumption), and requiring a minimum of design effort and test effort due to its simplicity. The resulting amplified difference signal typically has a curve which is zero at the desired temperature Tset, and is positive resp. negative when the temperature Tcomp of the integrated electrical component is higher resp. lower than the desired temperature Tset, or vice versa. A control loop can use this amplified difference signal to engage the heater 21 of the oven 2 when the temperature of the integrated electrical component is lower than the desired temperature Tₛₑₜ. It thereby typically uses more heating power when the amplified difference signal is larger.

In another embodiment the control circuit is adapted for comparing the first and the second measurement signals, e.g. to determine which is larger than the other, and for providing the result of the comparison as the control signal.

This is another example of a simple control circuit requiring only minimal resources. A comparison can e.g. easily be achieved using a differential amplifier or an op-amp or comparator.

Preferably the first resp. second sensing element comprises a first resp. second electrical resistor having a first resp. second resistance value with a first resp. second temperature coefficient of resistance, the second temperature coefficient of resistance being different from the first temperature coefficient of resistance.

When using a pair of resistors having different temperature coefficients of resistance (TCRs) and appropriate sensing signals, (e.g. current signals with an amplitude inversely proportional to the resistance value of each resistor, or voltage signals directly proportional to the resistance value of each resistor), temperature dependent characteristics as described above, having an intersection point at Tset are obtained. This allows a control loop only functioning on the ratio between the measured signals, the system is thus said to be ratiometric.

By using relatively small sensing elements (i.e. the sensing elements occupying less space than a typical MEMS structure or large capacitor, the sensing elements can be located in close proximity of the integrated electrical component, such that the temperature of the sensing elements is substantially the same as that of the MEMS structure while occupying less space. Moreover, by choosing simple sensing elements such as resistors which need not be implemented in the substrate, but may e.g. also be deposited, these sensing elements may even be mounted above or on top of the integrated electrical component itself, reducing the temperature difference between the sensing elements and the integrated electrical component even further.

Optionally the system further comprises a post-compensation circuit for removing residual errors in the system, the post-compensation circuit being connected to the control circuit for receiving the control signal and having components for generating a post-compensation signal, e.g. as a linear or quadratic or polynomial transformation of the control signal, or e.g. using a look-up table, and connected back into the system for supplying the post-compensation signal as a bias signal or an offset signal for reducing the difference between the temperature of the integrated electrical component and the predefined temperature.

By using such a post-compensation circuit residual errors, e.g. caused by inaccuracies due to offsets or due to thermal latency or due to other non-idealities may be further reduced.

In an embodiment the ovenized system comprises a substantially vacuum package in which the heating means and the integrated electrical component are located, the integrated electrical component being sufficiently thermally isolated from an ambient temperature, the heating means being in good thermal contact with the integrated electrical component.

It is also an aim of the present invention to provide a method for stabilizing a temperature of a integrated electrical component at a predefined temperature. This aim is achieved by a method having the characteristics of the independent method claim.

### BRIEF DESCRIPTION OF THE DRAWINGS

The invention is further elucidated in the appending figures and figure description explaining preferred embodiments of the invention. Note that the figures are not drawn to the scale. The figures are intended to describe the principles of the invention. Further embodiments of the invention can use combinations of the different features and elements of the different drawings.

FIG. 1 shows a MEMS resonator applied in an oscillator and filter.

FIG. 2 shows a plot of typical frequency drift over temperature of an oven controlled quartz crystal and for an uncompensated MEMS resonator.

FIG. 3 shows a prior art MEMS based system.

FIG. 4 shows another prior art MEMS based system.

FIG. 5A shows a top view of a typical MEMS resonator structure without sensing resistors.

FIG. 5B shows a top view of the MEMS resonator of FIG. 6A, on top of which sensing resistors having different TCR's are placed in close proximity and good thermal contact with the MEMS resonator, according to the invention.

FIG. 5C shows a cross section of the structure of FIG. 5A, according to line A-A, whereby the sensing resistors are placed next to each other.

FIG. 5D shows an alternative cross-section, whereby the sensing resistors are placed on top of each other.

FIG. 5E shows a vacuum package comprising a MEMs device according to an embodiment of the present invention.

FIG. 6 shows an embodiment of the system according to the present invention.

FIG. 7A shows an example of measurement voltage signals corresponding to temperature dependent resistor values.

FIG. 7B shows the difference between the measured voltage signals of FIG. 7A.

FIG. 7C shows the output of a comparison between the measured voltage signals of FIG. 7A.

FIG. 8 shows an embodiment of the system according to the present invention, showing also the heater.

FIG. 9 shows a first and a second temperature dependent characteristic.

FIG. 10 shows the system of FIG. 8 with a post-compensation control loop added.

FIG. 11 gives an impression of the stability of an output signal for an oven controlled MEMS parameter without dual sensor control, with dual sensor control according to the present invention, and with dual sensor and post-compensation control according to the present invention.

FIG. 12 shows an embodiment of FIG. 10 whereby the post compensation signal is a bias voltage of the MEMS structure.

FIG. 13 shows another variant of FIG. 10 whereby the post compensation signal acts upon a phase locked loop.

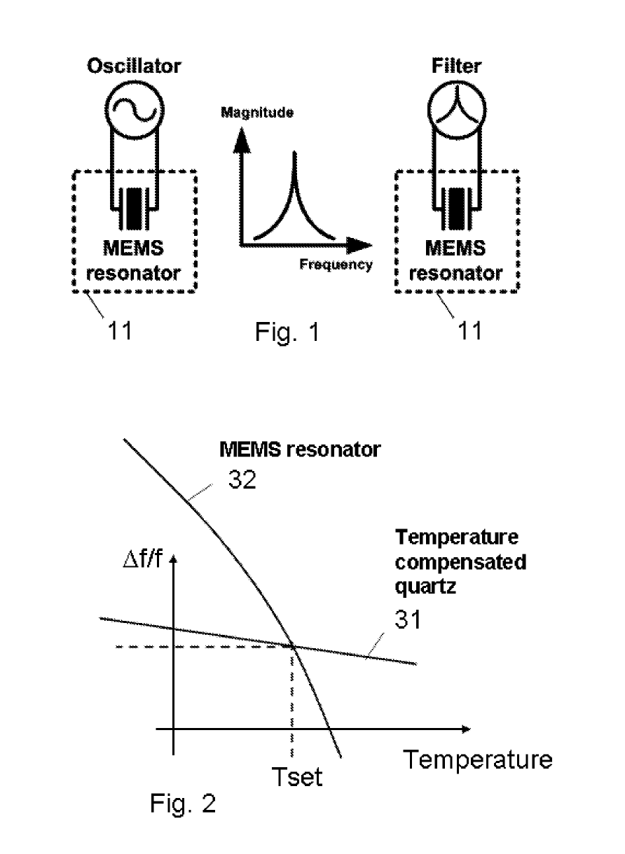

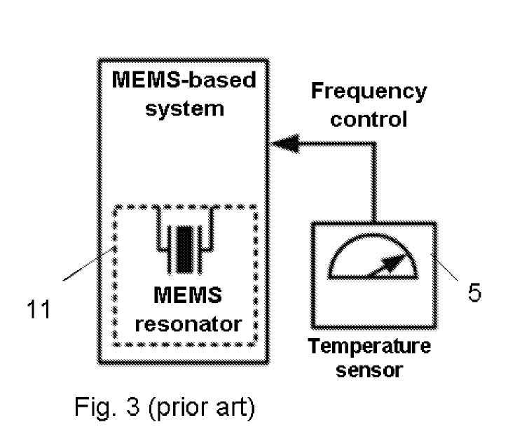

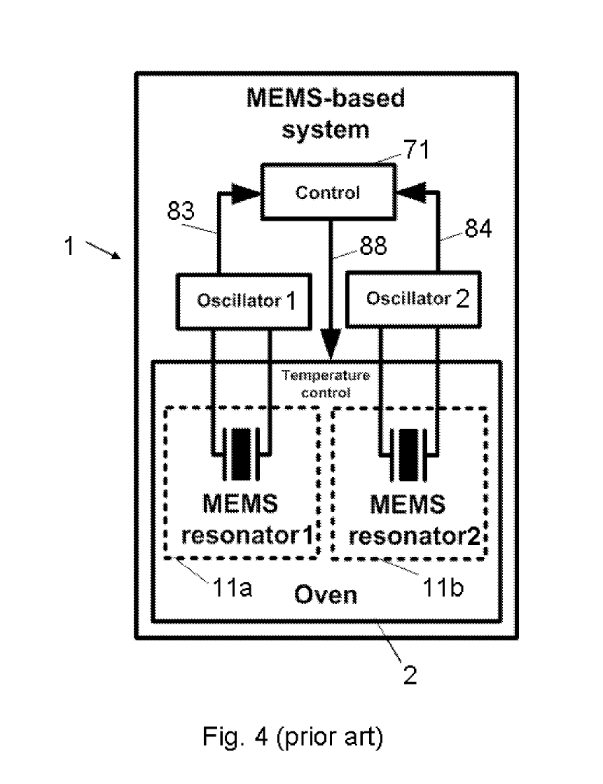

### DETAILED DESCRIPTION OF PREFERRED EMBODIMENTS

### References

1 system
11 MEMS structure, MEMS component, MEMS device
2 oven
21 heater, heating means
22 vacuum package
31 frequency curve of a temperature compensated quartz crystal versus temperature
32 frequency curve of an uncompensated MEMS resonator versus temperature
5 temperature sensor
6 reference temperature sensor
61 first sensing element
62 second sensing element
63 temperature dependent characteristic of first sensing element
64 temperature dependent characteristic of second sensing element
65 intersection point
7 electrical device
71 control circuit
81 first sensing signal
82 second sensing signal
83 first measurement signal
84 second measurement signal
85 difference signal
86 comparison signal
87 output signal
88 control signal
90 post compensation circuit
91 post compensation signal
92 output signal including post-compensation
Toven oven temperature
Tamb ambient temperature
Tset predefined temperature
Tcomp temperature of the integrated electrical component

The present invention will be described with respect to particular embodiments and with reference to certain drawings but the invention is not limited thereto. The drawings described are only schematic and are non-limiting. In the drawings, the size of some of the elements may be exaggerated and not drawn on scale for illustrative purposes. The dimensions and the relative dimensions do not necessarily correspond to actual reductions to practice of the invention.

Furthermore, the terms first, second, third and the like in the description and in the claims, are used for distinguishing between similar elements and not necessarily for describing a sequential or chronological order. The terms are interchangeable under appropriate circumstances and the embodiments of the invention can operate in other sequences than described or illustrated herein.

Moreover, the terms top, bottom, over, under and the like in the description and the claims are used for descriptive purposes and not necessarily for describing relative positions. The terms so used are interchangeable under appropriate circumstances and the embodiments of the invention described herein can operate in other orientations than described or illustrated herein.

The term “comprising”, used in the claims, should not be interpreted as being restricted to the means listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting of only components A and B. It means that with respect to the present invention, the only relevant components of the device are A and B.

The present invention provides a method and a system for stabilizing a temperature of a micro-electromechanical (MEMS) device 11 at a predefined temperature Tₛₑₜ. MEMS structures 11 are generally known, and are used for a wide variety of applications, such as pressure sensors, resonators, stress sensors, etc. One of their biggest advantages is that they are small and can be integrated in e.g. CMOS chips.

A problem with MEMS structures 11 however is that their characteristics may heavily drift with temperature, which is for example the case with a MEMS resonator the frequency of which may drift e.g. with 5000 ppm in a 100° C. temperature range (e.g. from −20° C. to +80° C.). For example, a silicon based MEMS resonator typically has a −30 ppm/K sensitivity to temperature with respect to its resonance frequency fᵣₑₛ(T). It is said that its temperature coefficient of frequency TCF is −30 ppm/K.

There are several techniques for stabilizing the frequency of a MEMS resonator 11, one is by electrical compensation, e.g. by modifying the feedback signal of the oscillator circuit (not further discussed herein), another is by keeping the temperature T_{comp} of the MEMS structure 11 stable at a predefined temperature Tₛₑₜ. The latter can e.g. be done by placing the MEMS structure 11 in an oven 2 and by maintaining the oven temperature Toven, the latter however requires some means of determining if the temperature inside the oven is higher or lower than the predetermined value Tₛₑₜ. In the patent application US 2009/0243747 the latter is implemented by using two MEMS resonators having a different Temperature Coefficient of Frequency TCF1, TCF2, and to generate a control signal 88 based on mixing the frequencies. The principle used in the present invention provides a system and a method which is applicable not only to MEMS resonators, but is also applicable to other kinds of MEMS structures 11, such as e.g. accelerometers or pressure sensors.

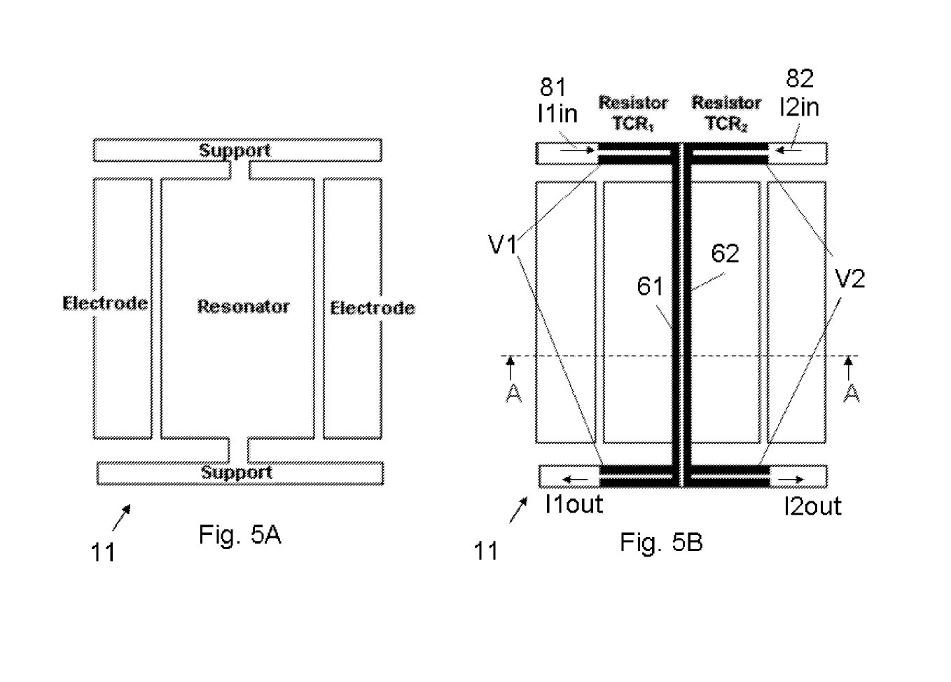

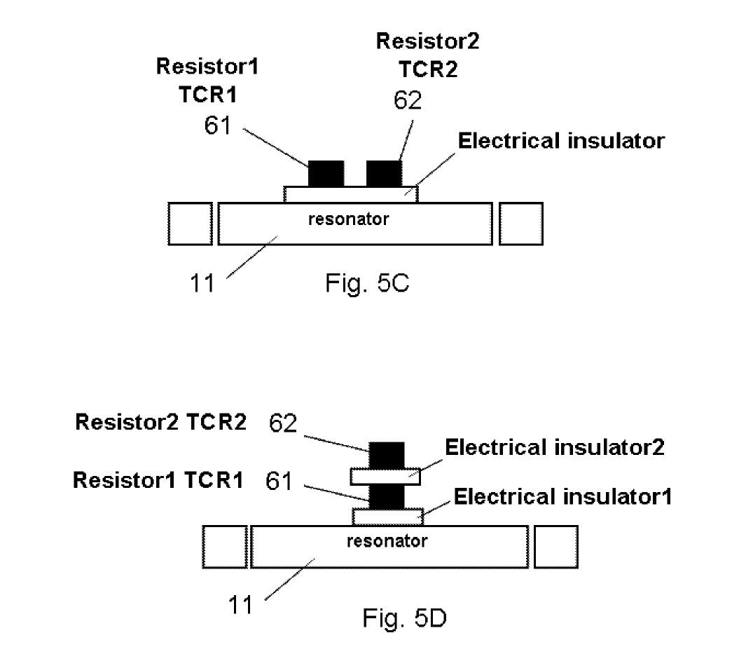

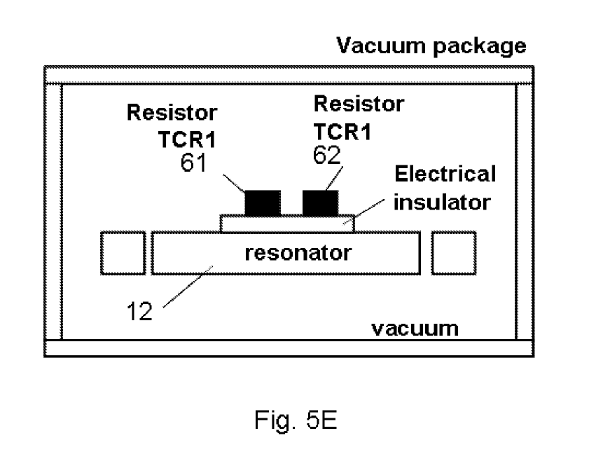

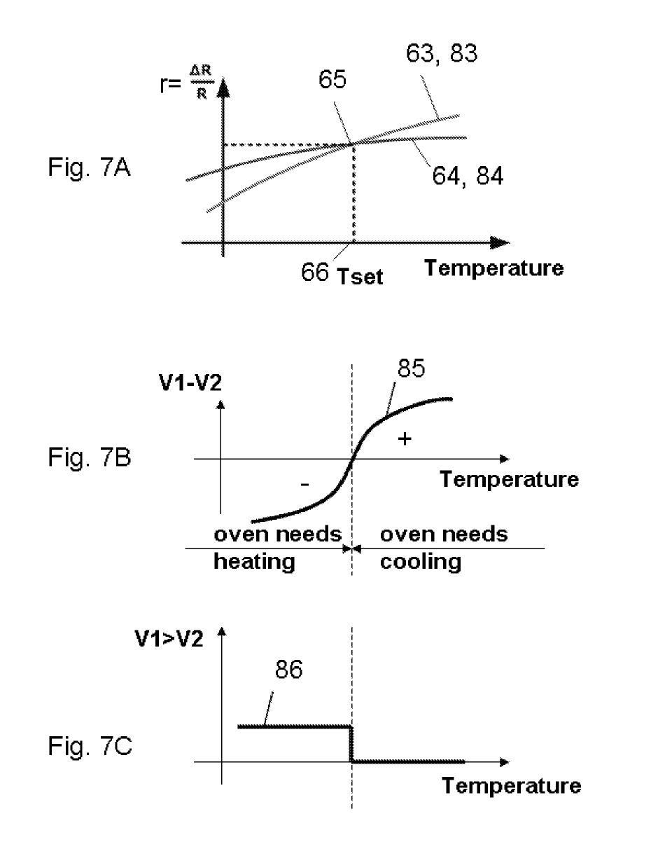

Referring to FIG. 5B, according to an embodiment of the present invention at least two resistors 61, 62 having a first resp. second resistance value r1, r2 and having a temperature coefficient of resistance TCR1 resp. TCR2, are processed on top of the resonator bar of a MEMS resonator 11 in an electrically insulated way, but in good thermal contact thereto, sufficient for the desired accuracy of the system. The resistance values are chosen in combination with two sensing signals 81 (I1in), 82 (I2in), e.g. a first DC current 81 running through the first resistor 61 and a second DC current 82 running through the second resistor 62 such that the resulting voltage curves 83, 84 (FIG. 7A) intersect in an intersection point 85 corresponding to the predefined temperature Tₛₑₜ. The resistors form the pair of sensing elements 61, 62 used for the dual temperature sensing according to the method of the present invention. In an embodiment the two sensing currents I1, I2 may be substantially the same, e.g. two DC currents generated by a current mirror by circuitry known in the art. In another embodiment a single sense signal (e.g. a DC current I1) may alternatively be applied to the first resp. the second sensing element 61, 62 (e.g. resistor), e.g. using a switch, while the corresponding first resp. second measurement result 83, 84 is stored on a first resp. a second storage means (e.g. measurement capacitors, not shown). After sensing, the measurement signals 83, 84 (e.g. voltages) stored on the storage means may be compared or subtracted for generating the control signal 88. In this way any differences between the first and the second sensing signals 81, 82 can be avoided.

Besides resistors also other elements may be used as sensing elements 61, 62, for example capacitors or diodes or combinations thereof, as long as intersecting temperature dependent characteristics 63, 64 can be obtained at a predefined temperature. Intersection can be created by simple scaling of the individual characteristics or other operations. The temperature characteristics need not to be the same for both elements (e.g. capacitance for one element and resistance for other element). It is well known that the resistance of a diode has a substantially exponential dependency on temperature, while the dependency of an electrical resistor is substantially linear, thus the temperature dependency is quite different. For simplicity the principles of the invention will be further described for resistors. For comparison, FIG. 5A shows the same MEMS resonator as FIG. 5B but without the temperature sensors 61, 62.

Referring back to FIG. 5B, in an embodiment the first and second sensing signals 81, 82 are generated by the electrical device 7. They may e.g. be generated in the same chip that comprises the MEMS device 11. In another embodiment the sensing signals 81, 82 are supplied from outside the electrical device 7, e.g. from outside the oven 2. The desired intersection point 65 (FIG. 7A) and the corresponding desired temperature Tₛₑₜ may be fixed or may be variable or tunable by changing the sensing signals 81, 82. Allowing external sensing signals 81, 82 to be supplied also allows performing some corrections or calibrations.

By placing the two resistors 61, 62 in thermal contact with the MEMS structure 11, in particular to the resonator bar, makes sure that the temperature Tcomp of the resonator bar is as closely as possible matched to the predefined temperature Tₛₑₜ, during operation of the electrical device 7 (e.g. chip), thereby stabilizing the resonator frequency of this MEMS 11 as good as possible, as the resonator frequency is most sensitive to the local temperature of the resonator bar. Note that during the operation of the electrical device (e.g. chip), there is typically a temperature difference between the inside of the oven Toven and the temperature of the MEMS device 11. Therefore the placement of the sensing elements 61, 62 close to the MEMS device, is more accurate than using a temperature sensor placed inside the oven but outside of the chip.

FIG. 5C shows a cross section of the structure of FIG. 5B, where the sensing resistors 61, 62 are located on an electrical insulator which is placed on top of the resonator. In this way thermal contact but electrical insulation is achieved. FIG. 5D shows another embodiment according to the present invention. It is clear to the person skilled in the art that many other topologies can be used.

In an embodiment, the integrated electrical component, e.g. a chip with a MEMS device 11, is placed in a vacuum package 22. A heating means 21 is foreseen in the package. The package 22 provides thermal isolation from the MEMS device 11 to the ambient temperature on the outside of the vacuum package, and together with the heating means 21 forms the oven 2 or ovenized system 1. In a preferred embodiment, the MEMS element 11 can be heated by steering current trough its support legs, heating the MEMS device 11 through Joule heating. Any other type of heating means 21 can be used, as far as MEMS element 11 and the temperature sensing means 61, 62 are in good thermal contact, that is to say, have substantially the same temperature.

Preferably, sensing elements 61, 62 are placed next to each other or above each other on top, below or next to the MEMS element 11, separated by electrically insulating but thermally conductive layers. Any other implementation providing good thermal contact and not severely deteriorating the MEMS element performance 11 can also be used.

The different TCR values may e.g. be achieved by using two different materials for the resistors 61, 62 required for the dual sensor loop. FIG. 7A shows an example of the relative electrical resistance r=ΔR/R of the first and of the second resistors 61, 62 versus temperature T, or in general the temperature dependent characteristics 63, 64 of the first and the second sensing elements 61, 62.

The existence and production of electrical resistors having predefined TCR values is well known in the art. For example, the temperature coefficient of resistance TCR for n- or p-type silicon depends on the doping concentration, according to known formulas. A. Razborsek and F Schwager describe in “Thin film systems for low RCR resistors” how resistors comprising TaN overlayed with Nipads with adjustable TCR's between −150 ppm/° C. and +500 ppm/° C. can be produced. U.S. Pat. No. 7,659,176 describes tunable temperature coefficient of resistance resistors and method of fabricating same. The TCR value of a resistor may vary by using different materials, but resistors comprising the same materials but having different crystal structure or crystal orientation, or a different doping level or impurity level may also have different TCR values.

In a small temperature range around Tₛₑₜ, the curves of the temperature dependent characteristics 63, 64 can be approximated by the formula:

R(T)=R₀(1+αΔT) (1)

whereby α is a material characteristic, called the temperature coefficient of resistance, known as TCR. Even though the term “resistor” is used, it is clear to the person skilled in the art that also parallel or series combinations of two or more individual resistors may be used to obtain a combined resistor with a combined resistance value r1 and a combined TCR1 value.

In an embodiment of the present invention using resistors as sensing elements, one of the TCR-values is substantially zero, while the other TCR value is positive.

In another embodiment, one of the TCR-values is substantially zero, while the other TCR value is negative.

In another embodiment, one of the TCR-values is negative while the other TCR value is positive.

In another embodiment, both TCR-values are negative but having a different value.

In another embodiment, both TCR-values are positive but having a different value.

In an embodiment of the present invention, the first and second sensing signals 81, 82 are AC resp. DC currents and the first and second measurement signals 83, 84 are AC resp. DC voltages.

In another embodiment the first and second sensing signals 81, 82 are AC resp. DC voltages and the first and second measurement signals 83, 84 are AC resp. DC currents.

The sensing signals 81, 82 may be continuous signals or intermitted signals.

In an embodiment of the control circuit 71 the measurement signals 83, 84 (e.g. voltages) coming from the sensing elements 61, 62 (e.g. resistors) are subtracted and optionally amplified, yielding for example a difference signal 85 as shown in FIG. 7B (or the inverse thereof, depending if the first measurement signal is subtracted from the second or vice versa). Optionally one of the measurement signals 83, 84 can be scaled before the subtraction. When the difference signal 85 of FIG. 7B is positive, the temperature Tcomp of the MEMS device 11 is higher than Tₛₑₜ, and the oven 2 should be cooled, which in case of passive cooling may be achieved by not powering the heater 21. When the difference signal 85 is negative, the temperature Tcomp of the MEMS device 11 is lower than Tₛₑₜ, and the oven 2 needs to be heated. In practice the oven temperature Tₒᵥₑₙ is typically chosen at least 10° C. above the ambient temperature, so that passive cooling can be used. The actual heating power supplied to the heater 21 may e.g. be proportional to the amplitude of the difference signal 85, or quadratic or exponential or another relationship. In other words, the method can involve comparing a temperature characteristic (e.g. resistance) of one temperature sensor 61 to a temperature characteristic (e.g. resistance) of a second temperature sensor 62. Via a temperature control loop the oven temperature Tₒᵥₑₙ is driven to the temperature Tₛₑₜ where the characteristics intersect (difference of comparison result is zero), such that the output of the MEMS structure 11 (e.g. a frequency in case of a MEMS resonator) is tuned to generate a stable output signal. The method can be used in connection with all kinds of MEMS structures including oscillators, filters, mixers and others. The method can also be used in connection with other integrated electrical elements, other than for electro-mechanical purposes, such as for stabilizing the characteristics of resistors or capacitor.

In another embodiment the measurement signals 83, 84 are compared to each other, e.g. using a comparator (not shown), yielding for example a comparison signal 86 as shown in FIG. 7C. When the signal 86 of FIG. 7C is positive, the temperature T of the MEMS device 11 is lower than Tₛₑₜ, and the oven 2 should be heated. Depending on the comparator configuration, other comparison signals 86 may be generated, e.g. clipping to a positive or negative voltage, but the person skilled in the art can easily adapt such signal as required by the heating means 21.

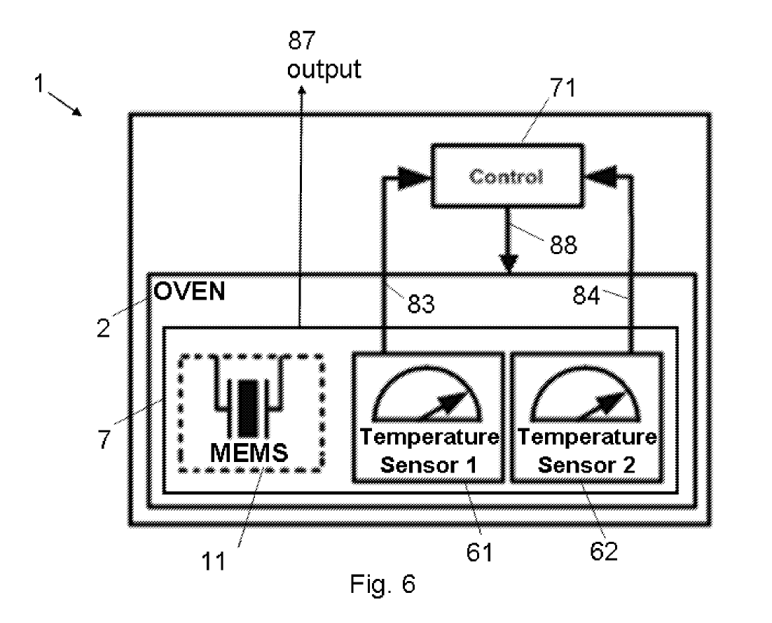

FIG. 6 illustrates an embodiment of the system 1 according to the present invention. The control of the oven temperature Tₒᵥₑₙ is based on the ratio or difference of characteristics between two elements 61, 62. The system 1 comprises an oven 2 wherein an electrical device comprising a MEMS device 11 is placed, the electrical device 7 comprising a MEMS structure 11 and two temperature sensors 61, 62 having different temperature dependent characteristics 63, 64 as explained above, for example two resistors R1 and R2 with TCR1 and TCR2 respectively. The system further comprises a control circuit 71 implementing a control loop for controlling or setting the temperature Tcomp of the MEMS structure 11, in particular of an element 11 thereof, to a fixed or desired temperature Tₛₑₜ. The control circuit 71 may be part of the electrical device 7 or part of the oven 2. The system operates as follows. The variation of the resistance r of each resistor R1, R2 is illustrated in FIG. 7A and is noted as functions r1(T) and r2(T). Both resistances are a function of the temperature T. In the temperature range of consideration, there is one (and only one) point where r1(T) and r2(T) are equal. This point is defined by a predetermined temperature Tₛₑₜ. For this temperature: r1(Tₛₑₜ)=r2(Tₛₑₜ), which equation is only valid at Tₛₑₜ, the targeted oven temperature. A control loop controls the oven temperature such that r1(Tₛₑₜ)=r2(Tₛₑₜ). When this is realized, the temperature of the oven is Tₛₑₜ, and maintained at Tₛₑₜ. In fact, Tₛₑₜ lies at the intersection of the measurement curves 83, 84 which is the same as the intersection of the characteristic curves when the sensing signals 61; 62 are identical, otherwise the curves are a factor m shifted, m being the ratio of the amplitude of the sensing signals 61, 62.

In steady state operation the temperature of the MEMS device 11 is maintained at Tₛₑₜ, and the temperature drift is removed. If the control loop has infinite gain at DC (an integrator), this control loop achieves absolute average temperature accuracy in absence of other circuit non-idealities, such as temperature-dependent offset in the sensing circuitry.

The control loop 71 may be implemented in an analog or digital way, using any algorithm known by the person skilled in the art. Additionally the control loop 71 may provide a circuit for controlling and monitoring the MEMS structures 11 in the oven 2. The control loop can in general contain any element or mechanism needed to effectively operate the system 7 or to tune the output signal 87 (e.g. the frequency of the resonator of the MEMS structure in FIG. 6) as desired. In particular, the control loop will ensure that the temperature of the MEMS device 11 is maintained at Tₛₑₜ. Signal quality factors and parameters of the Mems structure 11 may also be recorded and/or monitored by the control loop. Factors such as thermal variations, noise, elasticity, stress, pressure, applied strain and electrical biases including voltage, electric field and current as well as resonator materials, properties and structure may affect the output of the resonator 11. Monitoring these factors may be useful to develop a relationship between a resonator's output signal's contributing factors and the resonator's output signal characteristics. Understanding these relationships allows one to have more control over the generated output signal 87.

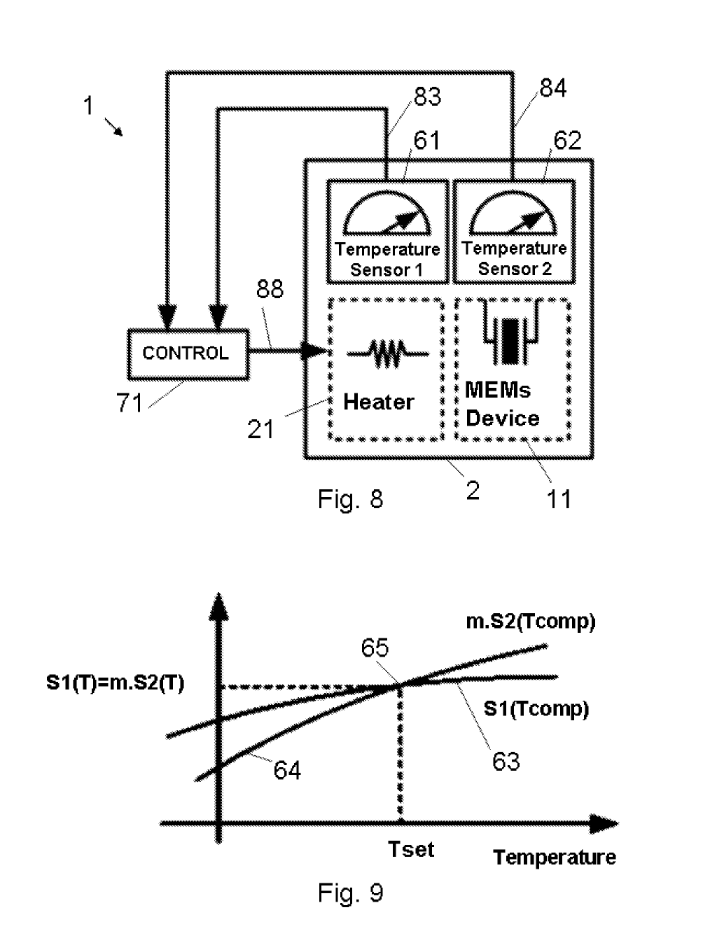

FIG. 8 is a variation of FIG. 6, showing an ovenized system 1 according to the present invention. The purpose of the first and second sensing element 61, 62 and the control circuit 71 is to keeping the temperature inside the oven 2 stable, equal to Tₛₑₜ, regardless of the ambient temperature. As a result, the component parameter variations will be very small. Two temperature sensors 61, 62 sense the temperature of the MEMS component 11. The sensors 61, 62 have a different dependency on temperature. They output two temperature-dependent values S1 and S2, e.g. measurement voltages V1 and V2 as described above. The control loop 71 drives a heater 21 which controls the temperature Tcomp of the MEMS component 11. The control loop controls the oven temperature such that m*S2=S1, where m is a predefined constant real number. This equation is only valid at one single temperature Tₛₑₜ. Therefore, when the loop settles, the temperature of the component 11 is Tₛₑₜ, and thus its temperature-dependent parameters are stable. This is shown in FIG. 9.

It can be observed that the heater control signal 88 is a function of ambient temperature T_{amb}. Indeed, assume that the ambient temperature drops, then the component temperature in the micro-oven 2 will drop too, due to the ambient temperature surrounding the oven 2. Therefore, both S1 and m.S2 will change as well (they may increase or decrease, depending on the sign of the temperature dependency). This will trigger the control loop 71 to compensate the heater control signal 88 to heat up the oven 2 again to the targeted temperature Tₛₑₜ. Indeed, the loop will force m.S2 back equal to S1. It can be seen from this example that the control signal 74 is a function of the ambient temperature T_{amb}. Thus, the dual sensor temperature stabilizing loop 71 can be used as a temperature sensor.

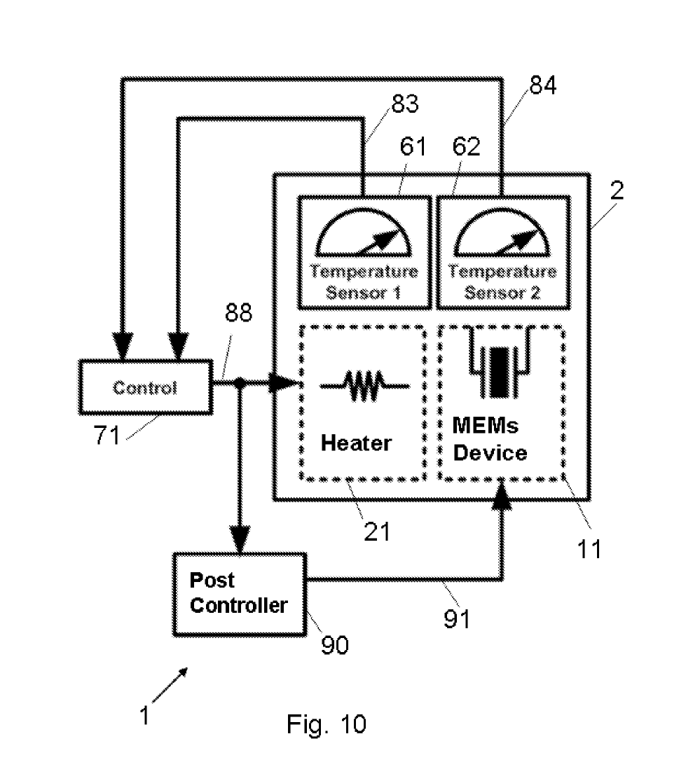

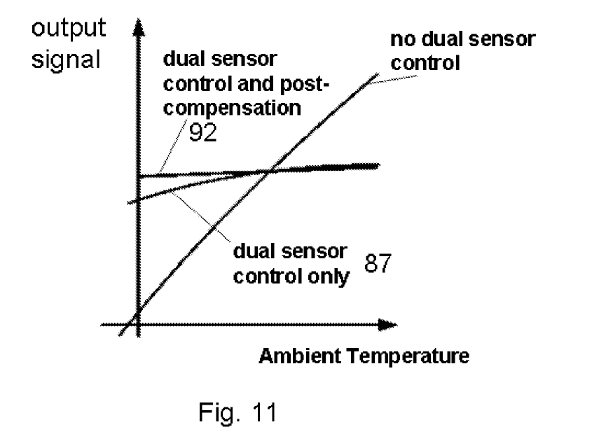

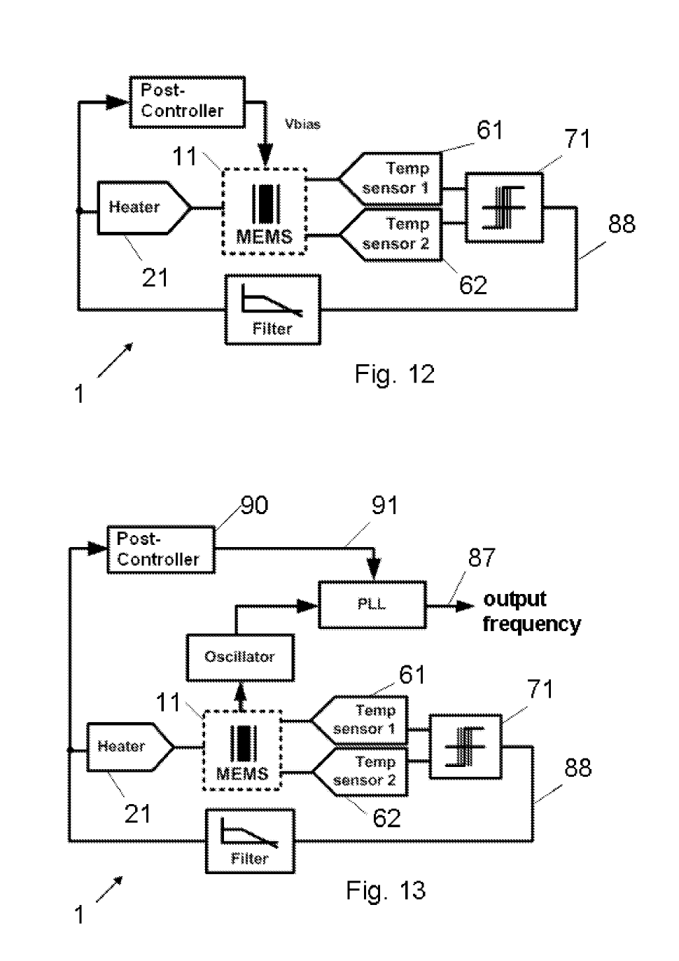

The dual sensor control loop 71, shown in FIG. 8, while theoretically perfect, may suffer from non-idealities in practice. This may result in a residual temperature dependency of the heated component parameters (e.g. frequency). In other words, while Tₛₑₜ is supposed to be fixed over ambient temperature variations, Tₛₑₜ may have a slight residual variation over ambient temperature, as shown in FIG. 11 (curve indicated by “dual sensor control only”). This means that the component parameters will still change over temperature, which is undesired. According to another aspect of the present invention, this residual temperature dependence may be further reduced by means of post compensation, as illustrated in FIG. 10. In this approach, the ambient temperature T_{amb} needs to be sensed. The measurement of T_{amb} then steers a compensation scheme, which corrects the non-ideal components of the loop. Since the original residual temperature drift due to nonidealities is small, the measurement of T_{amb} does not need not to be very accurate. The post compensation scheme can be of any independent kind which can impact the parameters of interest (e.g. resonator frequency), but not the temperature. For example, the control signal 88, representative for the ambient temperature T_{amb} may steer a bias voltage of the MEMS component 11 (FIG. 12). Another embodiment tunes a subsequent PLL (FIG. 13) which takes a MEMS oscillator as input and provides a tuned output frequency. This additional compensation 90 can be of any mathematic kind e.g. linear, quadratic or polynomial, or based on a look-up table, or based on any other compensation known by the person skilled in the art. The operation of the post-compensation 90 and the effect on the component parameters or output parameter 92 (e.g. frequency) is illustrated in FIG. 11, having a curve which is more flat than the curve 87 corresponding to the system without post-compensation 90.

As mentioned before, the dual sensor loop 71 may be implemented as an analog loop or a digital loop. Therefore, the ambient temperature output T_{amb} can be analog or digital, and the post-compensation scheme 90 can also be analog or digital.

While the post-compensation 90 can control an independent control signal (e.g. bias voltage of the MEMS component 11), it can also act on a temperature loop component. The post-compensation scheme 90 may also act on external parameters, not part of the system. For example, the ambient temperature measurement can serve as post compensation in the external system using the component parameters. For example, the post compensation can be done in an external PLL which uses an ovenized MEMS-based oscillator.

Summarizing, a control system 1 for controlling the temperature Tcomp for micro-electromechanical structures 11 is described herein. According to one aspect of the present invention a system 1 is provided. The system 1 comprises an oven 2 having a heat source 21, and a micro-electromechanical device 11 and two sensors 61, 62 (dual-sensor) having different temperature characteristics 63, 64, preferably two resistors having a different temperature coefficient of resistance TCR. The system 1 further comprises a control circuit 71 for performing a control loop for setting the temperature Tcomp to a fixed (or desired) temperature Tₛₑₜ. According to another aspect of the invention, a method is provided. The method comprises comparing/subtracting a temperature dependent characteristic 63, 64 of a first temperature sensor 61 to/from a temperature dependent characteristic 64 of a second temperature sensor 62. A control loop 71 sets the temperature Tcomp of the Mems structure 11 to a fixed (or desired) temperature Tₛₑₜ based on the output of the comparison/subtraction. Optionally the control signal 88 for the heater 21 may be used as a representation of the ambient temperature T_{amb}, and may be used to drive a post-compensation loop 90 to compensate for residual errors in the system 1. This post-compensation 90 can be e.g. a bias voltage for a MEMS device, an offset to a PLL, etc, or any other control signal independent of the temperature loop.

1-24. (canceled)

25. An ovenized system comprising:
a heating means configured to heat the ovenized system to an oven temperature Tₒᵥₑₙ;
an electrical device placed in the ovenized system, the electrical device comprising an integrated electrical component having a temperature dependent characteristic;
a temperature sensing means configured to sense a sensed temperature T_{comp} of the integrated electrical component, wherein the temperature sensing means comprises:
(i) a first sensing element in thermal contact with the integrated electrical component, thereby having substantially the sensed temperature T_{comp}, wherein the first sensing element has a first temperature dependent characteristic, and
(ii) a second sensing element in thermal contact with the integrated electrical component, thereby having substantially the sensed temperature T_{comp}, wherein the second sensing element has a second temperature dependent characteristic that differs from the first temperature dependent characteristic, and wherein the first temperature dependent characteristic and the second temperature dependent characteristic intersect at a predefined temperature Tₛₑₜ,
(iii) a sensing circuit configured to sense from the first sensing element a first measurement signal indicative of the first temperature dependent characteristic, and sense from the second sensing element a second measurement signal indicative of the second temperature dependent characteristic; and
a control circuit connected to the temperature sensing means and the heating means, wherein the control circuit is configured to:
(i) receive from the sensing means the first measurement signal and the second measurement signal, and
(ii) supply to the heating means a control signal to maintain the sensed temperature T_{comp} of the integrated electrical component at the predefined temperature Tₛₑₜ.

26. The ovenized system of claim 25, wherein:
the first sensing element is sensed with a first sensing signal; and
the second sensing element is sensed with a second sensing signal that is substantially identical to the first sensing signal.

27. The ovenized system of claim 25, wherein the control circuit is further configured to:
subtract the first measurement signal and the second measurement signal, resulting in a difference signal;
amplify the difference signal; and
provide the amplified difference signal as the control signal.

28. The ovenized system of claim 25, wherein the control circuit is further configured to:
compare the first measurement signal and the second measurement signal, resulting in a comparison; and
provide the comparison as the control signal.

29. The ovenized system of claim 25, wherein:
the first sensing element comprises a first electrical resistor having a first resistance value with a first temperature coefficient of resistance; and
the second sensing element comprises a second electrical resistor having a second resistance value with a second temperature coefficient of resistance, wherein the second temperature coefficient of resistance is different from the first temperature coefficient of resistance.

30. The ovenized system of claim 25, wherein:
the first sensing element comprises a diode having the first temperature dependent characteristic; and
the second sensing element comprises an electrical resistor having a resistance value with a temperature coefficient of resistance.

31. The ovenized system of claim 25, further comprising:
a post-compensation circuit connected to the control circuit, wherein the post-compensation circuit is configured to:
receive the control signal from the control circuit;
transform the control signal to generate a post-compensation signal; and
supply the post-compensation signal to the ovenized system as a bias signal or an offset signal, thereby reducing a difference between the temperature T_{comp} of the integrated electrical component and the predefined temperature Tₛₑₜ.

32. The ovenized system of claim 31, wherein transforming the control signal comprises performing a polynomial transformation of the control signal.

33. The ovenized system of claim 31, further comprising a look-up table, wherein transforming the control signal comprises transforming the control signal using the look-up table.

34. The ovenized system of claim 25, further comprising a vacuum package in which the heating means and the integrated electrical component are located, wherein the vacuum package is configured to thermally isolate the integrated electrical component from an ambient temperature, and wherein the heating means is in thermal contact with the integrated electrical component.

35. The ovenized system of claim 25, wherein the integrated electrical component is a microelectromechanical system (MEMS) device.

36. The ovenized system of claim 35, wherein the MEMS device comprises a MEMS oscillator, wherein the temperature dependent characteristic of the integrated electrical circuit comprises a temperature dependent resonance frequency of the MEMS oscillator.

37. A method comprising:
providing an ovenized system comprising a heating means configured to heat the ovenized system to an oven temperature Tₒᵥₑₙ;
providing an electrical device in the ovenized system, the electrical device comprising an integrated electrical component having a temperature dependent characteristic;
an electrical device placed in the ovenized system,
using a temperature sensing means to sense a sensed temperature T_{comp} of the integrated electrical component, wherein the temperature sensing means comprises:
(i) a first sensing element in thermal contact with the integrated electrical component, thereby having substantially the sensed temperature T_{comp}, wherein the first sensing element has a first temperature dependent characteristic, and
(ii) a second sensing element in thermal contact with the integrated electrical component, thereby having substantially the sensed temperature T_{comp}, wherein the second sensing element has a second temperature dependent characteristic that differs from the first temperature dependent characteristic, and wherein the first temperature dependent characteristic and the second temperature dependent characteristic intersect at a predefined temperature Tₛₑₜ,
(iii) a sensing circuit configured to sense from the first sensing element a first measurement signal indicative of the first temperature dependent characteristic, and sense from the second sensing element a second measurement signal indicative of the second temperature dependent characteristic;
using a control circuit connected to the temperature sensing means and the heating means to receive from the sensing means the first measurement signal and the second measurement signal; and

38. The method of claim 37, wherein:
the first sensing element is sensed with a first sensing signal; and
the second sensing element is sensed with a second sensing signal that is substantially identical to the first sensing signal.

39. The method of claim 37, wherein the control circuit is further configured to:
subtract the first measurement signal and the second measurement signal, resulting in a difference signal;
amplify the difference signal; and
provide the amplified difference signal as the control signal.

40. The method of claim 37, wherein the control circuit is further configured to:
compare the first measurement signal and the second measurement signal, resulting in a comparison; and
provide the comparison as the control signal.

41. The method of claim 37, wherein:
the first sensing element comprises a first electrical resistor having a first resistance value with a first temperature coefficient of resistance; and
the second sensing element comprises a second electrical resistor having a second resistance value with a second temperature coefficient of resistance, wherein the second temperature coefficient of resistance is different from the first temperature coefficient of resistance.

42. The method of claim 37, wherein:
the first sensing element comprises a diode having the first temperature dependent characteristic; and
the second sensing element comprises an electrical resistor having a resistance value with a temperature coefficient of resistance.

43. The method of claim 37, further comprising:
using a post-compensation circuit connected to the control circuit to:
(i) receive the control signal from the control circuit,
(ii) transform the control signal to generate a post-compensation signal, and
(iii) supply the post-compensation signal to the ovenized system as a bias signal or an offset signal, thereby reducing a difference between the temperature T_{comp} of the integrated electrical component and the predefined temperature Tₛₑₜ.

44. The method of claim 43, wherein transforming the control signal comprises performing one of a linear transformation, a quadratic transformation, and a polynomial transformation.

45. The method of claim 43, wherein transforming the control signal comprises transforming the control signal using a look-up table.

46. The method of claim 37, wherein:
the ovenized system comprises a vacuum package in which the heating means and the integrated electrical component are located;
the vacuum package is configured to thermally isolate the integrated electrical component from an ambient temperature; and
the heating means is in thermal contact with the integrated electrical component.

47. The method of claim 37, wherein the integrated electrical component is a microelectromechanical system (MEMS) device.

48. The method of claim 47, wherein the MEMS device comprises a MEMS oscillator, wherein the temperature dependent characteristic of the integrated electrical circuit comprises a temperature dependent resonance frequency of the MEMS oscillator.
